(19) United States
(12) Patent Application Publication
(10) Pub. No.: US 2005/0046003 A1
(43) Pub. Date: Mar. 3, 2005

(54) Stacked-chip semiconductor package and fabrication method thereof

(76) Inventor: Chung-Che Tsai, Hsinchu (TW)

Correspondence Address: ANDERSON KILL & OLICK, P.C., 1251 Avenue of the Americas, New York, NY, 10020, US

(21) Appl. No.: 10/649,884

(22) Filed: Aug. 26, 2003

(51) Int. Cl. H01L 21/44; H01L 23/48

(52) U.S. Cl. 257/686; 257/777; 257/782; 438/109

(57) ABSTRACT

A stacked-chip semiconductor package and a fabrication method thereof are provided in which a thermal blocking member is applied over an opening formed through a chip carrier, with a first chip being mounted on the thermal blocking member and a second chip being attached oppositely to the thermal blocking member and received within the opening; the first and second chips are electrically connected to the chip carrier by bonding wires. An encapsulant is formed on the chip carrier for encapsulating the second chip and having a cavity for receiving and exposing the first chip that is a light sensitive chip. By the thermal blocking member interposed between the first and second chips, heat produced from the second chip is prevented from passing to the first chip, thereby not damaging the first chip or causing warpage of the first chip, which can thus assure reliable performances of the semiconductor package.

### FIELD OF THE INVENTION

The present invention relates to semiconductor packages and fabrication methods thereof, and more particularly, to a stacked-chip semiconductor package incorporated with at least two stacked chips interposed by a thermal blocking member therebetween, and a method for fabricating the semiconductor package.

### BACKGROUND OF THE INVENTION

Semiconductor packages are electronic devices for accommodating active components such as semiconductor chips, whose structure is primarily composed of a chip mounted on a chip carrier (such as substrate, lead frame, etc.) and electrically connected to the chip carrier by means of conductive elements such as bonding wires; an encapsulant is formed by a resin compound (such as epoxy resin, etc.) on the chip carrier to encapsulate the chip and bonding wires which are protected against external moisture and contaminant. The encapsulant is usually opaque or non-transparent, thereby making a light sensitive chip that requires light for operation not suitably incorporated in such a semiconductor package.

Accordingly, a semiconductor package with a structurally modified encapsulant for allowing light to reach a light sensitive chip is provided as illustrated in FIG. 5. In this semiconductor package, a light sensitive chip 20 such as CMOS (complementary metal oxide semiconductor) chip is mounted on a substrate 21 and electrically connected to the substrate 21 by a plurality of bonding wires 22. An encapsulant 23 is formed on the substrate 21 and shaped as a wall structure surrounding the chip 20 and bonding wires 22; this wall-shaped encapsulant 23 thus forms a cavity 24 where the chip 20 and bonding wires 22 are received and exposed without being encapsulated by the encapsulant 23. A lid 25 is attached to an opening of the cavity 24 to hermetically isolate the chip 20 from the external atmosphere; this lid 25 is preferably made of a transparent material such as glass to allow light to penetrate through the lid 25 and reach the chip 20 to facilitate operation of the chip 20.

In order to enhance performances of the semiconductor package, it is preferable to incorporate multiple chips for example in a stack manner in a single semiconductor package. With respect to a light sensitive chip, a multi-chip package structure is exemplified as illustrated in FIG. 6, wherein the substrate 21 is formed with an opening 210 penetrating through an upper surface 211 and a lower surface 212 of the substrate 21. The light sensitive chip 20, referred to as “first chip” hereinafter, is mounted on the upper surface 211 of the substrate 21 in a face-up manner that an active surface 200 of the first chip 20 faces upwardly and an inactive surface 201 of the first chip 20 covers the opening 210 of the substrate 21; the first chip 20 is electrically connected to the upper surface 211 of the substrate 21 by the plurality of bonding wires 22 (hereinafter referred to as “first bonding wires”). A second chip 26 is attached to inactive surface 201 of the first chip 20 and received within the opening 210 of the substrate 21; the second chip 26 is electrically connected to the lower surface 212 of the substrate 21 by a plurality of second bonding wires 27. The encapsulant 23 formed on the substrate 21 has a first portion 230 on the upper surface 211 of the substrate 21 and a second portion 231 on the lower surface 212 of the substrate 21. The first portion 230 is shaped as a wall structure with the cavity 24 for receiving the first chip 20 and first bonding wires 22 which are covered by the lid 25 sealing the opening of the cavity 24, and the second portion 231 of the encapsulant 23 is used to encapsulate the second chip 27 and second bonding wires 27. By incorporation of multiple chips (first and second chips), performances of the semiconductor package can be desirably enhanced.

In the case of the second chip 27 being a high heat production chip such as flash memory chip or DSP (digital signal processor) chip, by direct contact between the first and second chips, a large amount of heat produced from the second chip would directly transfer to the first chip (for example, a low heat production CMOS chip) and thus damages the first chip or causes the first chip to warp. Such chip warpage, however, degrades reliability of the semiconductor package during operation; for example, an image captured by a warped chip (first chip 20) may be deformed, thereby adversely affecting performances of the semiconductor package.

Therefore, the problem to be solved herein is to provide a stacked-chip semiconductor package which can prevent chip warpage and ensure reliable performances of the semiconductor.

### SUMMARY OF THE INVENTION

An objective of the present invention is to provide a stacked-chip semiconductor package and a fabrication method thereof, in the use of a thermal blocking member applied between two stacked chips, to prevent chip warpage from occurrence and assure reliable performances of the semiconductor package.

Another objective of the invention is to provide a stacked-chip semiconductor package and a fabrication method thereof, in the use of a thermal blocking member applied between two stacked chips, to direct dissipation of heat produced from chips incorporated in the semiconductor package.

A further objective of the invention is to provide a stacked-chip semiconductor package and a fabrication method thereof, which can enhance performances of the semiconductor package by operation of multiple chips incorporated therein.

In accordance with the foregoing and other objectives, the present invention proposes a stacked-chip semiconductor package, including: a chip carrier having an upper surface and an opposite lower surface and formed with an opening penetrating therethrough; a thermal blocking member applied at predetermined area on the upper surface of the chip carrier and over the opening, wherein the thermal blocking member has a first surface directed away from the opening and an opposite second surface facing toward the opening; a first chip mounted on the first surface of the thermal blocking member and electrically connected to the upper surface of the chip carrier at area free of the thermal blocking member; a second chip mounted on the second surface of the thermal blocking member and received within the opening of the chip carrier, allowing the second chip to be electrically connected to the lower surface of the chip carrier; an encapsulant for encapsulating the second chip and having a cavity for receiving and exposing the first chip; and an infrared filter and a lens supported by the encapsulant, wherein the infrared filter is positioned above the first chip and the lens is disposed above the infrared filter, allowing light to penetrate through the lens and infrared filter to reach the first chip.

In another embodiment, the semiconductor package is further incorporated with a third chip stacked on the second chip, allowing the third chip to be electrically connected to the lower surface of the chip carrier and encapsulated by the encapsulant. The first, second and third chips are electrically connected to the chip carrier respectively by a plurality of bonding wires. The first chip can be a light sensitive chip such as a CMOS (complementary metal oxide semiconductor) chip, the second chip can be a flash memory chip, and the third chip can be a DSP (digital signal processor) chip, for example; a CMOS chip is a low heat production chip, and flash memory and DSP chips are high heat production chips. The chip carrier is a substrate formed with the opening penetrating through the same, or a lead frame having a plurality of leads surrounding the opening.

The above stacked-chip semiconductor package provides significant benefits. In the use of a thermal blocking member applied between two stacked first and second chips, a large amount of heat produced by the second chip (flash memory chip) and/or third chip (DSP chip) are prevented from passing to the first chip (low heat production CMOS chip), and dissipation of the heat from the second and third chips is directed away from the first chip. As a result, the first chip would not suffer or be damaged by the large amount of heat from the second and third chips, which can thus protect the first chip from being warped and assure reliable performances of the semiconductor package, for example, making an image captured by the first chip not be deformed by a warped CMOS chip. Moreover, the above semiconductor package provides a chip stack structure including a light sensitive chip (first chip) such as CMOS chip stacked with other types of chips such as flash memory chip and/or DSP chip, thereby enhancing performances of the semiconductor package by operation of multiple chips.

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional view of a semiconductor package according to a first preferred embodiment of the invention;

FIGS. 2A-2E are schematic diagrams showing procedural steps for fabricating the semiconductor package shown in FIG. 1;

FIG. 3 is a cross-sectional view of a semiconductor package according to a second preferred embodiment of the invention;

FIG. 4 is a cross-sectional view of a semiconductor package according to a third preferred embodiment of the invention;

FIG. 5 (PRIOR ART) is a cross-sectional view of a conventional semiconductor package; and

FIG. 6 (PRIOR ART) is a cross-sectional view of another conventional semiconductor package.

### DETAILED DESCRIPTION OF THE PREFERRED EMBODIMENTS

The preferred embodiments of a stacked-chip semiconductor package and a fabrication method thereof proposed in the present invention are described with reference to FIGS. 1, 2A-2E, 3 and 4.

### First Preferred Embodiment

As shown in FIG. 1, a stacked-chip semiconductor package according to a first preferred embodiment of the invention is a substrate-based package structure, including: a substrate 10 formed with an opening 100 penetrating therethrough; a thermal blocking member 11 applied over the opening 100 of the substrate 10; a first chip 12 mounted on a surface of the thermal blocking member 11 and electrically connected to the substrate 10; a second chip 13 mounted on an opposite surface of the thermal blocking member 11 and received within the opening 100 of the substrate 10; an encapsulant 14 for encapsulating the second chip 13 and having a cavity 140 for receiving and exposing the first chip 12; and an infrared filter 15 and a lens 16 supported by the encapsulant 14 and disposed above the first chip 12, allowing light to penetrate through the lens 16 and infrared filter 15 to reach the first chip 12.

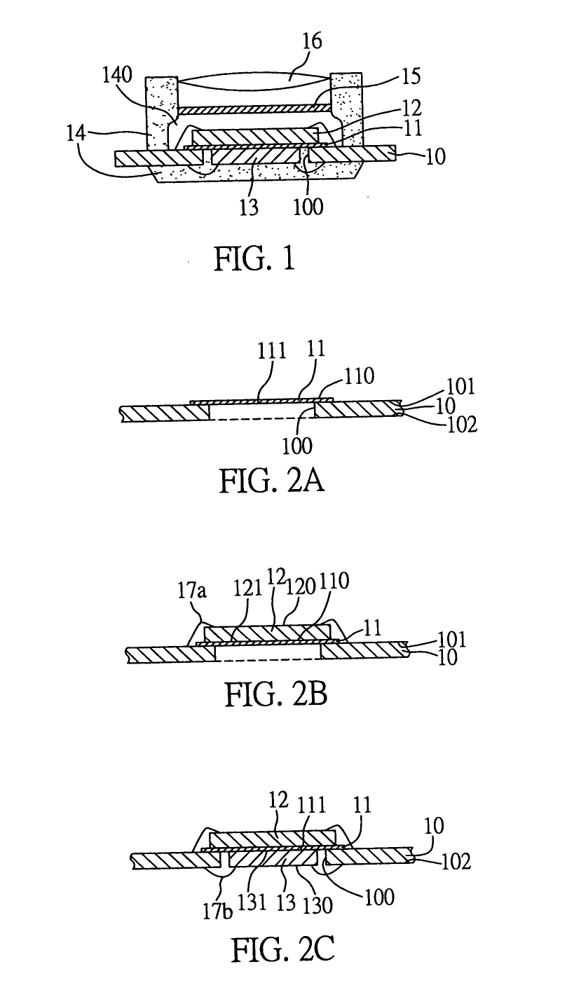

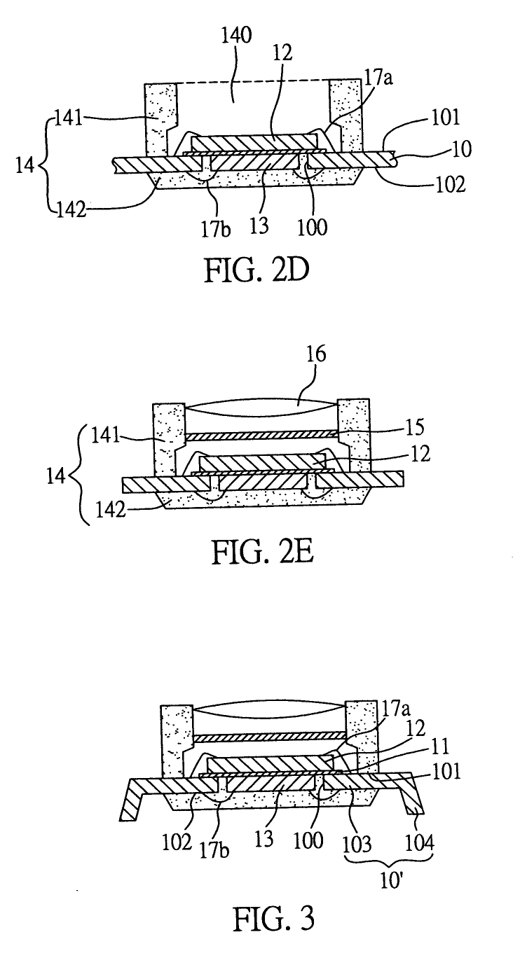

The above stacked-chip semiconductor package can be fabricated by a series of procedural steps illustrated in FIGS. 2A-2E.

Referring to FIG. 2A, the first step is to prepare a substrate 10 having an upper surface 101 and an opposite lower surface 102 and form an opening 100 penetrating through the substrate 10. The substrate 10 serves as a chip carrier and is primarily made of a conventional resin material such as epoxy resin, polyimide resin, BT (bismaleimide triazine) resin, FR4 resin, etc.

The next step is to apply a thermal blocking member 11 at predetermined area on the upper surface 101 of the substrate 10 and over the opening 100. The thermal blocking member 11 is made of a thermal resistant material and has a first surface 110 directed away from the opening 100 and an opposite second surface 111 facing toward the opening 100.

Referring to FIG. 2B, a first chip 12 having an active surface 120 and an opposite inactive surface 121 is prepared, the active surface 120 being formed with a plurality of electronic elements and circuits (not shown) thereon. The first chip 12 is mounted on the thermal blocking member 11 in a face-up manner that the inactive surface 121 of the first chip 12 is attached to the first surface 110 of the thermal blocking member 11, and the active surface 120 of the first chip 12 faces upwardly. Then, a wire-bonding process is performed to form a plurality of first bonding wires 17a that are bonded to bond pads (not shown) on the active surface 120 of the first chip 12 and to bond fingers (not shown) on the upper surface 101 of the substrate 10 so as to electrically connect the first chip 12 to the substrate 10. The first chip 12 can be a light sensitive chip such as a CMOS (complementary metal oxide semiconductor) chip, which is a low heat production chip.

Referring to FIG. 2C, a second chip 13 having an active surface 130 (where electronic elements and circuits, not shown, are formed) and an opposite inactive surface 131 is prepared. The second chip 13 is mounted and received within the opening 100 of the substrate 10 in a face-down manner that the inactive surface 131 of the second chip 13 is attached to the second surface 111 of the thermal blocking member 11, and the active surface 130 of the second chip 13 faces downwardly, such that the thermal blocking member 11 is interposed between the first and second chips 12, 13. Then, a plurality of second bonding wires 17b are formed and bonded to bond pads (not shown) on the active surface 130 of the second chip 13 and to bond fingers (not shown) on the lower surface 102 of the substrate 10 so as to electrically connect the second chip 13 to the substrate 10. The second chip 13 can be for example a flash memory chip, which is a high heat production chip.

Referring to FIG. 2D, a molding process is performed to form an encapsulant 14 by a conventional resin compound (such as epoxy resin, etc.) on the substrate 10. This encapsulant 14 has a first portion 141 formed on the upper surface 101 of the substrate 10 and a second portion 142 formed on the lower surface 102 of the substrate 10. The first portion 141 is a wall structure surrounding the first chip 12 and first bonding wires 17a and thus forms a cavity 140 where the first chip 12 and first bonding wires 17a are received and exposed without being encapsulated by the resin compound. The second portion 142 of the encapsulant 14 fills into the opening 100 of the substrate 10 and encapsulates the second chip 13 and second bonding wires 17b which are protected against external moisture and contaminant.

Referring to FIG. 2E, an infrared filter 15 and a lens 16 are mounted and supported by the first portion 141 of the encapsulant 14, wherein the infrared filter 15 is positioned above the first chip 12 and the lens 16 is disposed above the infrared filter 15. The infrared filter 15 and lens 16 are used to concentrate and filter light that penetrates therethrough and reaches the first chip 12 to facilitate operation of the first chip 12. This completes the semiconductor package according to the first preferred embodiment of the invention.

### Second Preferred Embodiment

FIG. 3 illustrates a semiconductor package according to a second preferred embodiment of the invention. As shown in FIG. 3, this semiconductor package is structurally similar to that of the above first embodiment but differs in that a lead frame 10′ is used as a chip carrier instead of the substrate 10 (FIG. 1). The lead frame 10′ is formed with a plurality of inner leads 103 surrounding the opening 100 and a plurality of outer leads 104 exposed to outside of the encapsulant 14, allowing the thermal blocking member 11 to be applied over the opening 100 and on an upper surface 101 of the leads 103. The first chip 12 mounted on the thermal blocking member 11 is electrically connected to the upper surface 101 of the leads 103 by the first bonding wires 17a, and the second chip 13 received within the opening 100 is electrically connected to a lower surface 102 of the leads 103 by the second bonding wires 17b. The exposed outer leads 104 are shaped or bent and serve as input/output (I/O) connections to electrically couple the semiconductor package to an external device such as printed circuit board (PCB, not shown).

### Third Preferred Embodiment

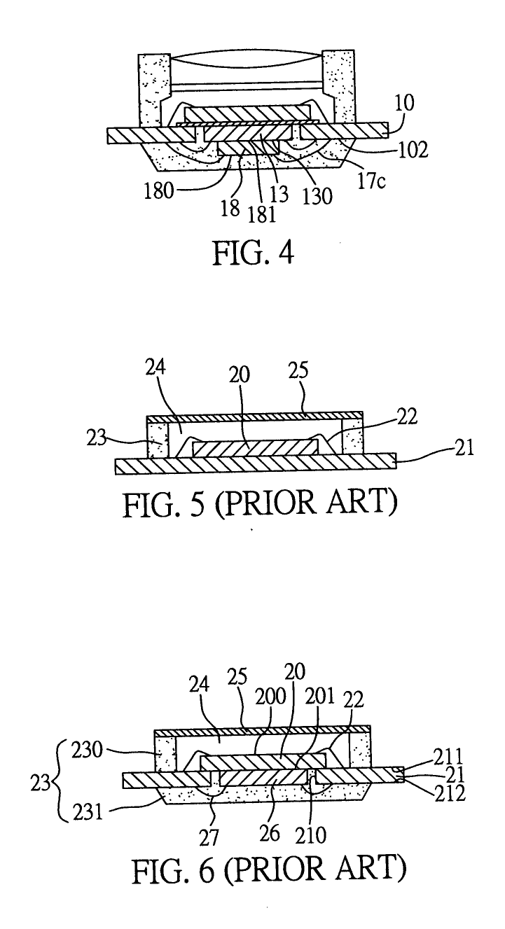

FIG. 4 illustrates a semiconductor package according to a third preferred embodiment of the invention. As shown in FIG. 4, this semiconductor package is structurally similar to that of the above first embodiment but differs in that a third chip 18 is further incorporated in the semiconductor package and stacked on the second chip 13. The third chip 18 has an active surface 180 and an opposite inactive surface 181, allowing the inactive surface 181 to be attached to the active surface 130 of the second chip 13 and electrically connected to the lower surface 102 of the substrate 10 by a plurality of third bonding wires 17c. The third chip 18 can be for example a DSP (digital signal processor) chip, which is a high heat production chip. Incorporation of the third chip 18 further enhances performances of the semiconductor package by operation of three chips together.

The above stacked-chip semiconductor package according to the invention provides significant benefits. In the use of a thermal blocking member applied between two stacked first and second chips, a large amount of heat produced by the second chip (flash memory chip) and/or third chip (DSP chip) are prevented from passing to the first chip (CMOS chip) that is a low heat production chip, and dissipation of the heat from the second and third chips is directed away from the first chip. As a result, the first chip would not suffer or be damaged by the large amount of heat from the second and third chips, which can thus protect the first chip from being warped and assure reliable performances of the semiconductor package, for example, making an image captured by the first chip not be deformed by a warped CMOS chip. Moreover, the semiconductor package according to the invention provides a chip stack structure including a light sensitive chip (first chip) such as CMOS chip stacked with other types of chips such as flash memory chip and/or DSP chip, thereby enhancing performances of the semiconductor package by operation of multiple chips.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

1. A stacked-chip semiconductor package, comprising:
a chip carrier having an upper surface and an opposite lower surface and formed with an opening penetrating therethrough;
a thermal blocking member applied at predetermined area on the upper surface of the chip carrier and over the opening, wherein the thermal blocking member has a first surface directed away from the opening and an opposite second surface facing toward the opening;
a first chip mounted on the first surface of the thermal blocking member and electrically connected to the upper surface of the chip carrier at area free of the thermal blocking member;
a second chip mounted on the second surface of the thermal blocking member and received within the opening of the chip carrier, allowing the second chip to be electrically connected to the lower surface of the chip carrier; and
an encapsulant for encapsulating the second chip and having a cavity for receiving and exposing the first chip.

2. The semiconductor package of claim 1, further comprising: a third chip stacked on the second chip and electrically connected to the lower surface of the chip carrier, allowing the third chip to be encapsulated by the encapsulant.

3. The semiconductor package of claim 1, further comprising: an infrared filter and a lens supported by the encapsulant, wherein the infrared filter is positioned above the first chip and the lens is disposed above the infrared filter, allowing light to penetrate through the lens and infrared filter to reach the first chip.

4. The semiconductor package of claim 1, wherein the first and second chips are electrically connected to the chip carrier by a plurality of bonding wires.

5. The semiconductor package of claim 2, wherein the third chip is electrically connected to the chip carrier by a plurality of bonding wires.

6. The semiconductor package of claim 1, wherein the chip carrier is a substrate.

7. The semiconductor package of claim 1, wherein the chip carrier is a lead frame having a plurality of leads surrounding the opening.

8. The semiconductor package of claim 3, wherein the first chip is a CMOS (complementary metal oxide semiconductor) chip.

9. The semiconductor package of claim 1, wherein the thermal blocking member is made of a thermal resistant material.

10. A fabrication method of a stacked-chip semiconductor package, comprising the steps of:
preparing a chip carrier having an upper surface and an opposite lower surface, the chip carrier being formed with an opening penetrating therethrough;
applying a thermal blocking member at predetermined area on the upper surface of the chip carrier and over the opening, wherein the thermal blocking member has a first surface directed away from the opening and an opposite second surface facing toward the opening;
mounting a first chip on the first surface of the thermal blocking member and electrically connecting the first chip to the upper surface of the chip carrier at area free of the thermal blocking member;
mounting a second chip on the second surface of the thermal blocking member to be received within the opening of the chip carrier, and electrically connecting the second chip to the lower surface of the chip carrier; and
forming an encapsulant for encapsulating the second chip and having a cavity for receiving and exposing the first chip.

11. The fabrication method of claim 10, further comprising a step of: stacking a third chip on the second chip and electrically connecting the third chip to the lower surface of the chip carrier, allowing the third chip to be encapsulated by the encapsulant.

12. The fabrication method of claim 10, further comprising a step of: mounting an infrared filter and a lens to be supported by the encapsulant, wherein the infrared filter is positioned above the first chip and the lens is disposed above the infrared filter, allowing light to penetrate through the lens and infrared filter to reach the first chip.

13. The fabrication method of claim 10, wherein the first and second chips are electrically connected to the chip carrier by a plurality of bonding wires.

14. The fabrication method of claim 10, wherein the third chip is electrically connected to the chip carrier by a plurality of bonding wires.

15. The fabrication method of claim 10, wherein the chip carrier is a substrate.

16. The fabrication method of claim 10, wherein the chip carrier is a lead frame having a plurality of leads surrounding the opening.

17. The fabrication method of claim 12, wherein the first chip is a CMOS (complementary metal oxide semiconductor) chip.

18. The fabrication method of claim 10, wherein the thermal blocking member is made of a thermal resistant material.
